(19) United States
(12) Patent Application Publication
(10) Pub. No.: US 2004/0070056 A1
(43) Pub. Date: Apr. 15, 2004

(54) Lead frame and method of manufacturing the same

(76) Inventors: Hideki Matsuzawa, Nagano (JP); Etsuo Uematsu, Nagano (JP)

Correspondence Address: ARMSTRONG, KRATZ, QUINTOS, HANSON & BROOKS, LLP, 1725 K STREET, NW, SUITE 1000, WASHINGTON, DC, 20006, US

(21) Appl. No.: 10/633,586

(22) Filed: Aug. 5, 2003

(30) Foreign Application Priority Data
Aug. 6, 2002 (JP) 2002-228661

(51) Int. Cl. H01L 21/44

(52) U.S. Cl. 257/666; 438/123

(57) ABSTRACT

In a lead frame, a die-pad is delimited for a semiconductor element to be mounted thereon, a plurality of leads are arranged along the periphery of an area to be ultimately separated as a semiconductor device for the die-pad, and furthermore, a conductor portion for power/ground terminal is formed around the die-pad in the area between the die-pad and the leads corresponding to the die-pad. The die-pad, the leads, and the conductor portion for power/ground terminal are supported by an adhesive tape. The conductor portion for power/ground terminal is formed in the form of a single or double rings around the corresponding die-pad, or formed to partially surround the corresponding die-pad. The conductor portion for power/ground terminal is connected to at least one lead among the plurality of leads.

### BACKGROUND OF THE INVENTION

1. Field of the Invention

The present invention relates to a lead frame for use in a leadless package (semiconductor device), such as a quad flat non-leaded (QFN) package, for mounting a semiconductor element. In particular, the present invention relates to a lead frame having a shape adapted to reduce the number of leads connected to power terminals and ground terminals in the case where a semiconductor element provided with a plurality of power terminals and the like is mounted on the lead frame, and also to a method of manufacturing the same.

In the following description, power terminals and ground terminals are referred to as “power/ground terminals” for convenience.

2. Description of the Related Art

FIGS. 1a to 1c schematically show the constitutions of a prior art lead frame and a semiconductor device using the same.

FIG. 1a shows the constitution seen from the top of a portion of the strip-shaped lead frame 10. This lead frame 10 has a frame structure formed of an outer frame 11 and an inner frame 12 (also referred to as a “section bar”) arranged in the form of a matrix inside the outer frame 11. Guide holes 13, which are engaged with a transfer mechanism when the lead frame 10 is transferred, are provided in the outer frame 11. A rectangular die-pad 14 on which a semiconductor element (chip) is mounted is located at the center portion of each opening portion defined by frames 11 or 12, and the die-pad 14 is supported by four support bars 15 extending from the four corners of the corresponding frames 11 and 12. Moreover, a plurality of leads 16 extend in the shape of a comb from each frame 11 or 12 toward the die-pad 14. Each lead 16 includes an inner lead portion 16a (FIG. 1b) which is electrically connected to an electrode terminal (a signal terminal or a power/ground terminal) of a semiconductor element to be mounted on the die-pad 14, and an outer lead portion (external connection terminal) 16b which is electrically connected to a wiring of a mounting board such as a motherboard. Also, broken lines CL represent partition lines used when the lead frame 10 is ultimately separated for each package (semiconductor device) in a package assembly process. Note that, although not explicitly shown in FIGS. 1a to 1c, all of the section bars (inner frames 12) are removed when the lead frame 10 is separated for each package.

FIG. 1b shows the cross-sectional structure of a semiconductor device 20 having a QFN package structure, which is manufactured using the above-described lead frame 10. In the semiconductor device 20, reference numeral 21 denotes a semiconductor element mounted on the die-pad 14, reference numerals 22 denote bonding wires each of which connects each electrode terminal of the semiconductor element 21 to the inner lead portion 16a of the corresponding lead 16, and reference numeral 23 denotes sealing resin for protecting the semiconductor element 21, the bonding wires 22, and the like.

Such a semiconductor device 20 (QFN package) can be basically manufactured as follows: the semiconductor element 21 is mounted on the die-pad 14 of the lead frame 10 (die bonding); each electrode terminal of the semiconductor element 21 is electrically connected to the corresponding lead 16 using the bonding wire 22 (wire bonding); the semiconductor element 21, the bonding wires 22, and the like are sealed with the sealing resin 23 (mass molding or individual molding); and then the lead frame 10 is separated for each package along the partition lines CL using a dicer or the like (dicing).

In such a package assembly process, when wire bonding is performed, each electrode terminal 21a (a signal terminal or a power/ground terminal) of the semiconductor element 21 is connected to the corresponding lead 16 in a one-to-one relationship using the bonding wire 22, as schematically shown in FIG. 1c. Therefore, in the case where a plurality of power/ground terminals are included in the electrode terminals 21a of the semiconductor element 21, each power/ground terminal is also connected to the corresponding lead 16 in a one-to-one relationship similarly.

In this case, each signal terminal among the electrode terminals 21a has different electrical properties, and therefore needs to be connected to the corresponding lead 16 in a one-to-one relationship. However, the power/ground terminals (particularly the ground terminals) have the same electric properties, and therefore do not necessarily need to be connected to the corresponding leads 16 in a one-to-one relationship. In other words, if there is a sufficient space for a bonding position of the wire 22 on each lead 16, it is also possible to connect two or more power/ground terminals together to one lead 16.

However, in the state of the art, each electrode terminal 21a of the semiconductor element 21 is, in almost cases, connected to the corresponding lead 16 in a one-to-one relationship as shown in FIG. 1c, in view of the fact that a wire bonding position on each lead is limited because the lead width and arrangement pitch of each lead are narrowed with the recent demand for increased numbers of pins.

In the prior art as described above, where wire bonding is performed in a package (semiconductor device) assembly process, each electrode terminal of a semiconductor element is connected to the corresponding lead in a one-to-one relationship. Therefore, there has been the following problem: in the case where a plurality of power/ground terminals are included in the electrode terminals of the semiconductor element, a considerable number of leads must be prepared for the power/ground terminals, for the number of the power/ground terminals, and thus the number of leads capable of being used for signal terminals is relatively reduced.

Incidentally, in recent semiconductor elements for 32-bit CPUs and the like, the number of power/ground terminals accounts for approximately 30 to 40% of the total number of external terminals (i.e., the number of signal terminals accounts for approximately 60 to 70% thereof).

In this case, the number of leads needs to be increased if the number of leads for signal terminals is less than the number of leads required for the semiconductor element. For this, both the lead width and arrangement pitch of each lead need to be narrowed, or the size of a lead frame (and thus the package) needs to be increased with the lead width and the like of each lead unchanged. However, the approach to narrow the lead width or the like of each lead involves difficulty in terms of technology (etching, stamping, or the like for patterning a lead frame). On the other hand, the approach to increase the size of a lead frame causes another problem in that costs for materials are increased.

Moreover, although each electrode terminal of a semiconductor element is connected to the corresponding lead of a lead frame in a one-to-one relationship, there has been a problem in that the degree of freedom of a wire bonding position is low due to the limitation in a wire bonding position on each lead, in view of the recent technology trends (due to an increasing number of pins, the lead width and the arrangement pitch have been narrower). This makes a wire bonding process difficult.

### SUMMARY OF THE INVENTION

An object of the present invention is to provide a lead frame which can contribute to reduce the size of a package by reducing the number of leads connected to power/ground terminals and which can increase the degree of freedom of a wire bonding position in the case where a semiconductor element provided with a plurality of power/ground terminals is mounted on the lead frame, and also to provide a method of manufacturing the same.

To attain the above object, according to a first aspect of the present invention, there is provided a lead frame comprising: a die-pad delimited for a semiconductor element to be mounted thereon; a plurality of leads arranged along a periphery of an area which is to be ultimately separated as a semiconductor device for the die-pad; a conductor portion for power/ground terminal formed to at least partially surround the die-pad in an area between the die-pad and the plurality of leads corresponding to the die-pad, wherein the die-pad, the plurality of leads, and the conductor portion for power/ground terminal are supported by an adhesive tape.

According to the constitution of the lead frame of the first aspect, in addition to the constitution of a normal lead frame (a die-pad and a plurality of leads corresponding to the die-pad), the conductor portion for power/ground terminal is formed so as to at least partially surround the die-pad. Therefore, the conductor portion can be used as a lead exclusively for a power/ground terminal.

Specifically, in the case where a semiconductor element provided with a plurality of power/ground terminals is mounted on the lead frame, if the conductor portion is connected to one lead among the plurality of leads, which is assigned exclusively for a power/ground terminal, each power/ground terminal of the semiconductor element can be connected to the common lead exclusively for a power/ground terminal by connecting each power/ground terminal to the conductor portion, not by connecting each power/ground terminal to the corresponding lead in a one-to-one relationship as in the prior art. In other words, the number of leads connected to the power/ground terminals of the semiconductor element can be reduced to a minimum of one. This eliminates the need for a considerable number of leads exclusively for power/ground terminals, which have been heretofore required. Thus, the size of a package (semiconductor device) can be reduced by the amount corresponding to the no longer required leads.

Moreover, the conductor portion is formed so as to at least partially surround the die-pad (i.e., over a relatively wide area). Accordingly, when wire bonding is performed in a package (semiconductor device) assembly process, a sufficient space is ensured for wire bonding positions on the conductor portion, thereby making it possible to improve the degree of freedom of a wire bonding position.

Also, according to a second aspect of the present invention, there is provided a lead frame comprising: a plurality of leads arranged along a periphery of an area which is to be ultimately separated as a semiconductor device for a semiconductor element mounting region; and a conductor portion for power/ground terminal formed to at least partially surround a periphery of the semiconductor element mounting region in an area between the semiconductor element mounting region and the plurality of leads corresponding to the semiconductor element mounting region, wherein the plurality of leads and the conductor portion for power/ground terminal are supported by an adhesive tape.

According to the constitution of the lead frame of the second aspect, similarly to the lead frame according to the above first aspect, the conductor portion for power/ground terminal is formed so as to at least partially surround the semiconductor element mounting region. Therefore, the number of leads connected to the power/ground terminals of a semiconductor element can be reduced by using the conductor portion as a lead exclusively for a power/ground terminal. Thus, the size of a package (semiconductor device) can be reduced, and the degree of freedom of a wire bonding position can be increased.

Also, according to another aspect of the present invention, there is provided a method of manufacturing a lead frame, comprising the steps of: forming a base frame by etching or stamping a metal plate, in which a plurality of unit base frames are linked to one another, and have a die-pad, a plurality of leads corresponding to the die-pad, and a conductor portion for power/ground terminal arranged for a semiconductor element to be mounted on the die-pad, the conductor portion at least partially surrounding the die-pad in an area between the die-pad and the plurality of leads, and being linked to the die-pad; forming a concave portion in a portion linking the conductor portion and the die-pad on one surface of the base frame; attaching an adhesive tape on the surface of the base frame where the concave portion is formed; and cutting off a portion of the base frame where the concave portion is formed.

Also, according to still another aspect of the present invention, there is provided a method of manufacturing a lead frame, comprising the steps of: forming a base frame by etching or stamping a metal plate, in which a plurality of unit base frames are linked to one another, and have a semiconductor element mounting region, a plurality of leads corresponding to the semiconductor element mounting region, and a conductor portion for power/ground terminal arranged for a semiconductor element to be mounted on the semiconductor element mounting region, the conductor portion at least partially surrounding the semiconductor element mounting region in an area between the semiconductor element mounting region and the plurality of leads, and being linked to at least one lead among the plurality of leads; forming a concave portion in a portion linking the conductor portion and the at least one lead on one surface of the base frame; attaching an adhesive tape on the surface of the base frame where the concave portion is formed; and cutting off a portion of the base frame where the concave portion is formed.

### BRIEF DESCRIPTION OF THE DRAWINGS

FIGS. 1a to 1c are views showing the constitution of a prior art lead frame and a semiconductor device using the same;

FIGS. 2a and 2b are views showing the constitution of a lead frame according to a first embodiment of the present invention;

FIG. 3 is a plan view showing an example of a manufacturing process of the lead frame of FIGS. 2a and 2b;

FIGS. 4a to 4d are cross-sectional views showing the manufacturing process subsequent to the manufacturing process of FIG. 3;

FIGS. 5a to 5c are cross-sectional views showing (part of) another example of a manufacturing process of the lead frame of FIGS. 2a and 2b;

FIGS. 6a and 6b are views showing an example of a semiconductor device using the lead frame of FIGS. 2a and 2b;

FIGS. 7a and 7b are views showing the constitution of a lead frame according to a second embodiment of the present invention;

FIG. 8 is a plan view showing (part of) an example of a manufacturing process of the lead frame of FIGS. 7a and 7b;

FIGS. 9a and 9b are views showing an example of a semiconductor device using the lead frame of FIGS. 7a and 7b;

FIGS. 10a and 10b are views showing the constitution of a lead frame according to a third embodiment of the present invention;

FIG. 11 is a plan view showing (part of) an example of a manufacturing process of the lead frame of FIGS. 10a and 10b;

FIGS. 12a and 12b are views showing the constitution of a lead frame according to a fourth embodiment of the present invention;

FIG. 13 is a plan view showing (part of) an example of a manufacturing process of the lead frame of FIGS. 12a and 12b;

FIGS. 14a and 14b are views showing an example of a semiconductor device using the lead frame of FIGS. 12a and 12b;

FIGS. 15a and 15b are views showing the constitution of a lead frame according to a fifth embodiment of the present invention;

FIG. 16 is a plan view showing (part of) an example of a manufacturing process of the lead frame of FIGS. 15a and 15b; and

FIGS. 17a and 17b are views showing an example of a semiconductor device using the lead frame of FIGS. 15a and 15b.

### DESCRIPTION OF THE PREFERRED EMBODIMENTS

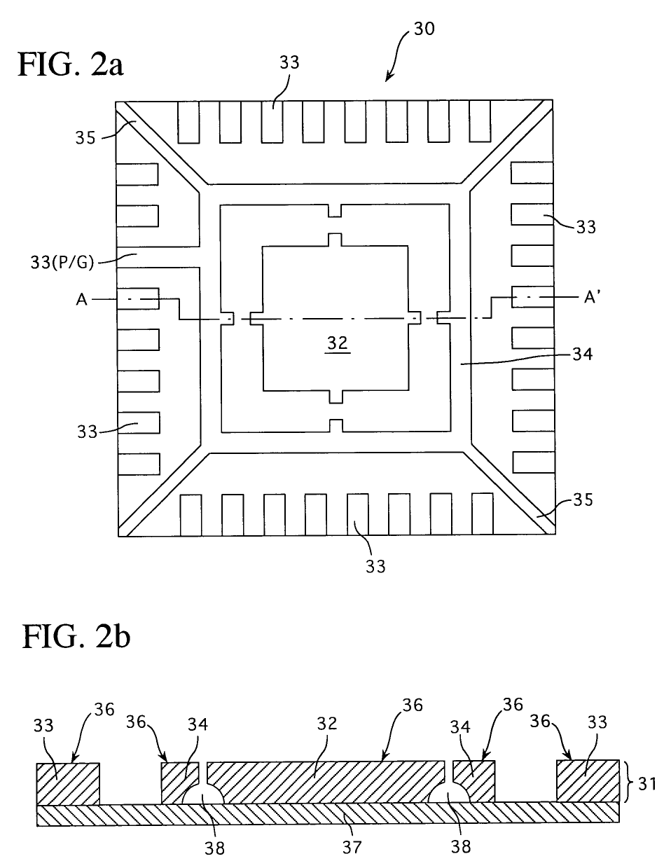

FIGS. 2a and 2b schematically show the constitution of a lead frame for use in a leadless package, such as a QFN package, according to a first embodiment of the present invention. In these drawings, FIG. 2a shows the constitution seen from the top of a portion of the lead frame, and FIG. 2b shows the cross-sectional structure of the lead frame seen along the A-A′ line in FIG. 2a.

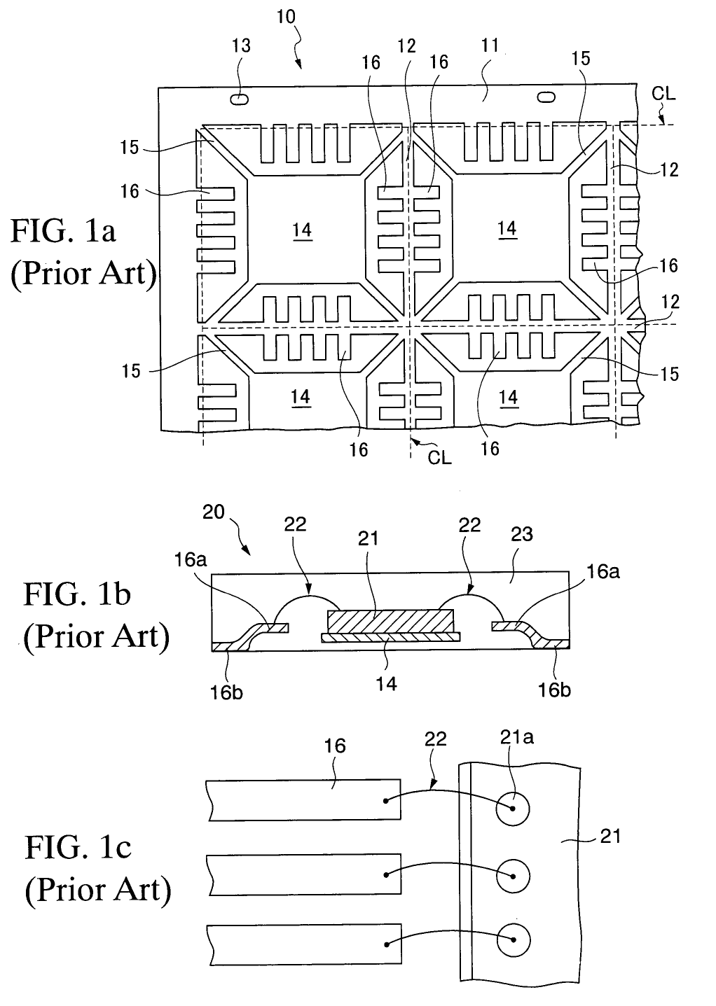

In FIGS. 2a and 2b, reference numeral 30 denotes part (a portion corresponding to an area to be ultimately separated as an individual semiconductor device) of the strip-shaped lead frame. The lead frame is basically made of a base frame 31 obtained by etching or stamping a metal plate. In this base frame 31, reference numeral 32 denotes a nearly rectangular die-pad which is delimited to correspond to each semiconductor element (chip) to be mounted thereon, and reference numeral 33 denotes a plurality of leads (32 leads in the example shown in these drawings) which are arranged to correspond to the die-pad 32. As shown in FIG. 2a, each lead 33 extends outward in the shape of a comb, separately from the die-pad 32, and is arranged along the periphery of the area to be ultimately separated as a semiconductor device. Each lead 33 includes an inner lead portion which is electrically connected to an electrode terminal (a signal terminal or a power/ground terminal) of a semiconductor element to be mounted thereon, and an outer lead portion (external connection terminal) which is electrically connected to a wiring of a mounting board such as a motherboard. Moreover, although not particularly shown in FIGS. 2a and 2b, each lead 33 arranged to correspond to the die-pad 32 is connected to a lead corresponding to an adjacent die-pad through a frame portion (portion denoted by reference numeral 12 in FIG. 1a), or connected to the outermost frame portion (portion denoted by reference numeral 11 in FIG. 1a).

Reference numeral 34 denotes a conductor portion for power/ground terminal, which characterizes the present invention. The conductor portion 34 is formed in the shape of a ring around the die-pad 32 in the area between the die-pad 32 and the plurality of leads 33 corresponding to the die-pad 32. As shown in FIG. 2a, the ring-shaped conductor portion 34 is connected to one lead 33(P/G) among the 32 leads, which is for power/ground terminal, and is supported by four support bars 35 extending from four corners of the frame portion (portions denoted by reference numerals 11 and 12 in FIG. 1a). In other words, each conductor portion 34 formed around each die-pad 32 is linked (connected) to one another through the corresponding four support bars 35 and the frame portion.

On the entire surface of the base frame 31, a metal film 36 is formed. On the backside (bottom surface in the example shown in FIG. 2b) of the base frame 31, an adhesive tape 37 is attached. The attachment (taping) of the adhesive tape 37 is basically performed as a counter measure to prevent sealing resin from leaking to the backside of the frame (also referred to as “mold flush”) during molding (plastic molding) in a package assembly process to be performed at a later stage. Furthermore, the adhesive tape 37 has the following functions: supporting the die-pad 32, the leads 33, the conductor portion 34, and the support bars 35 together with the frame portion; supporting the die-pad 32 so that the die-pad 32 separated from the conductor portion 34 may not fall off when linking portions (four portions in the present embodiment) between the die-pad 32 and the conductor portion 34 are cut off in a manufacturing process of the lead frame 30 as explained later; and supporting the individual leads 33 so that the leads 33 separated from the frame portion may not fall off when a predetermined portion of each lead 33 is cut off.

Reference numeral 38 denotes a concave portion formed by half-etching as described later. The portions (four portions) linking the die-pad 32 and the conductor portion 34 are selected as the positions where the concave portions 38 are formed, as described later.

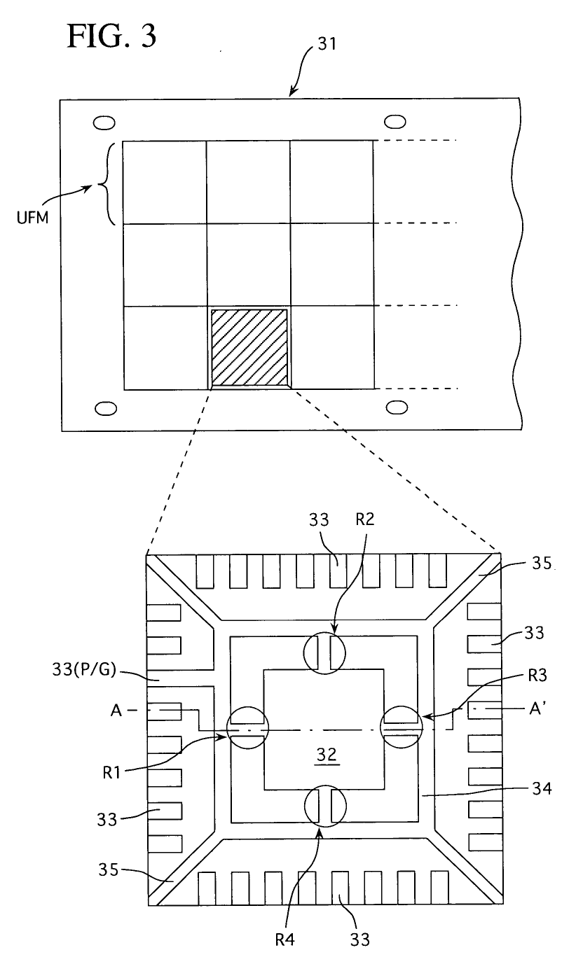

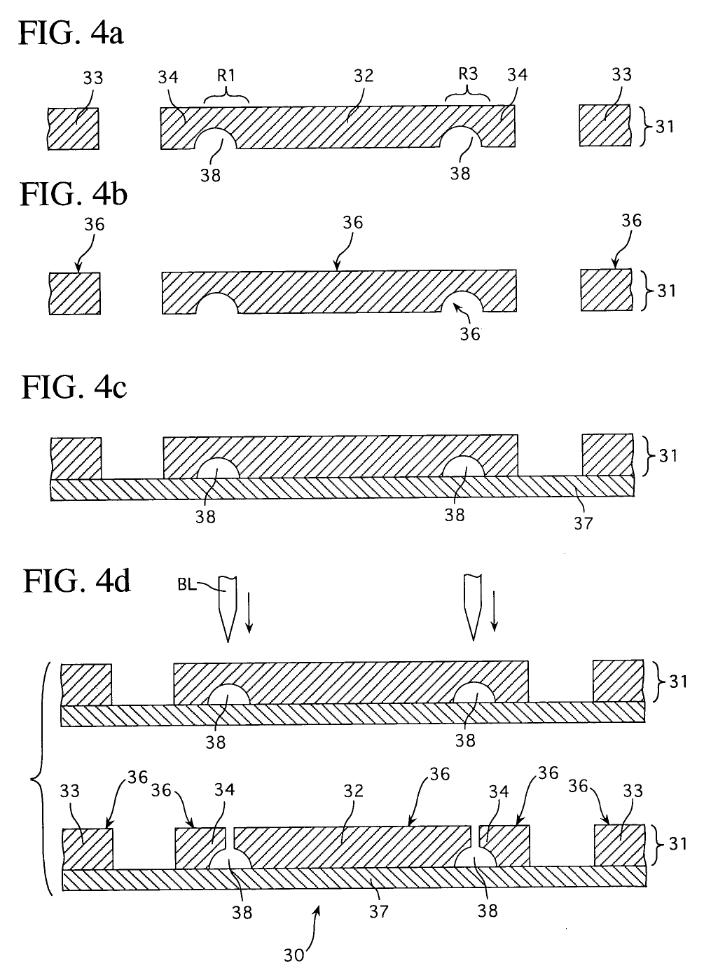

Next, a method of manufacturing the lead frame 30 according to the present embodiment will be described with reference to FIG. 3 and FIGS. 4a to 4d showing an example of the manufacturing process in sequence. Note that FIGS. 4a to 4d show the cross-sectional structures seen along the A-A′ line in FIG. 3.

First, in the first step (FIG. 3), a metal plate is etched or stamped to form the base frame 31.

As schematically shown in the upper portion of FIG. 3, the base frame 31 to be formed has a structure in which a plurality of unit base frames UFM, each assigned to each semiconductor element to be mounted thereon, are linked in the form of a matrix. In each unit base frame UFM, as schematically shown as a portion (portion indicated by hatching) except for the frame portion on the periphery of the unit base frame UFM in the lower portion of FIG. 3, the conductor portion 34 for power/ground terminal is formed in the shape of a ring around the die-pad 32 in the area between the die-pad 32 and the corresponding leads 33. The conductor portion 34 is connected to the one lead 33(P/G) for power/ground terminal, supported by the four support bars 35 extending from the four corners of the frame portion, and further connected to the die-pad 32 at four positions (portions surrounded by circles denoted by R1 to R4 in FIG. 3).

Incidentally, as material for the metal plate, for example, copper (Cu), Cu-based alloy, iron-nickel (Fe—Ni), Fe—Ni based alloy, or the like, is used. Moreover, the thickness of the metal plate (base frame 31) is selected to be approximately 200 μm.

In the next step (FIG. 4a), the concave portions 38 are formed by half-etching at predetermined portions on one surface (bottom surface in the example shown in FIG. 4a) of the base frame 31.

The four portions R1 to R4 linking the ring-shaped conductor portion 34 and the die-pad 32 in the constitution shown in FIG. 3 are selected as the above-described predetermined portions (positions where the concave portions 38 are formed).

Half-etching can be performed by, for example, wet etching after the entire surface of the base frame 31 except for the predetermined portions has been covered with a mask (not shown). Although the concave portions 38 are formed by half-etching in the present process, the concave portions 38 can be also formed by press work. The concave portions 38 are formed to a depth of approximately 160 μm.

In the next step (FIG. 4b), the metal film 36 is formed by electrolytic plating on the entire surface of the base frame 31 having the concave portions 38 formed therein.

For example, the surface of the base frame 31 is plated with nickel (Ni) for improving adhesion, using the base frame 31 as an electric supply layer. Then, the Ni layer is plated with palladium (Pd) for improving conductivity. Furthermore, the Pd layer is plated with gold (Au) flash, thus forming the metal film (Ni/Pd/Au) 36.

Although the metal film 36 is formed in the manufacturing process (process of FIG. 4b) of the lead frame in the present embodiment, the metal film does not necessarily need to be formed in this stage and may be formed in a later stage. For example, after molding (plastic molding) is performed in a package (semiconductor device) assembly process, a solder film (metal film) may be formed on the lead portions exposed from the sealing resin by electroless plating, printing, or the like.

In the next step (FIG. 4c), the adhesive tape 37 made of epoxy resin, polyimide resin, or the like, is attached to the surface (bottom surface in the example shown in FIG. 4c) of the base frame 31 where the concave portions 38 are formed.

In the final step (FIG. 4d), the portions where the concave portions 38 are formed, i.e., the portions (portions denoted by R1 to R4 in FIG. 3) linking the die-pad 32 and the ring-shaped conductor portion 34 are cut off, for example, in such a way that the portions are stamped out with a die (punch) or a blade BL. Thus, the lead frame 30 (FIGS. 2a and 2b) according to the present embodiment is manufactured.

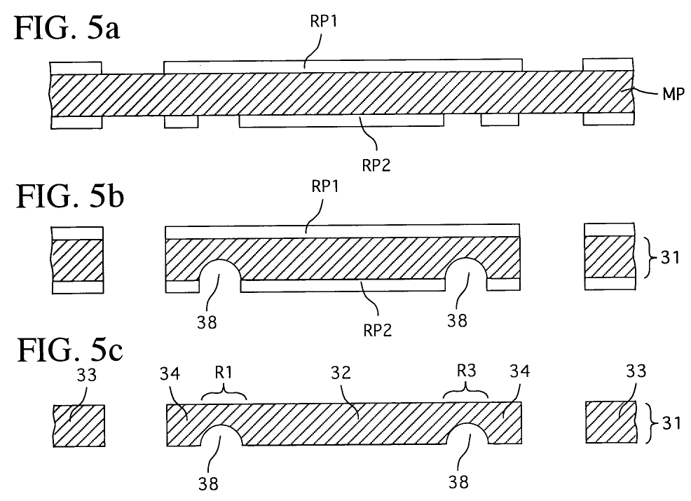

Although the formation (FIG. 3) of the base frame 31 and the formation (FIG. 4a) of the concave portions 38 are performed in different steps in the method of manufacturing the lead frame 30 according to the above-described embodiment, these formations can be also performed in the same step. An example of the manufacturing process in this case is shown in FIGS. 5a to 5c.

In the method illustrated in FIGS. 5a to 5c, first, etching resist is coated on both surfaces of a metal plate MP (e.g., a plate of Cu or Cu-based alloy). Then, the resist on both surfaces is respectively patterned by using masks (not shown) having predetermined patterns formed thereon, thus forming resist patterns RP1 and RP2 (FIG. 5a).

In this case, as for the resist pattern RP1 on the upper surface (surface where a semiconductor element is mounted), the resist is patterned so that areas of the metal plate MP corresponding to the die-pad 32, the leads 33, the conductor portion 34, the support bars 35, the portions R1 to R4 linking the conductor portion 34 and the die-pad 32, and the portions linking the conductor portion 34 and the lead 33(P/G) for power/ground terminal may be covered. On the other hand, as for the resist pattern RP2 on the lower surface, the resist is patterned so that the same area as that of the resist pattern RP1 on the upper surface may be covered and that areas corresponding to portions to be the concave portions 38 may be exposed.

After both surfaces of the metal plate MP are covered with the resist patterns RP1 and RP2 in this way, the formation of the base frame 31 and the formation of the concave portions 38 as shown in the lower portion of FIG. 3 are simultaneously performed by double-sided simultaneous etching (e.g., wet etching) (FIG. 5b).

Furthermore, the etching resist (RP1 and RP2) is removed to obtain the base frame 31 having such a structure as shown in FIG. 4a (FIG. 5c). The subsequent steps are the same as those shown in FIG. 4b and the subsequent drawings.

According to the method illustrated in FIGS. 5a to 5c, the formation of the base frame 31 and the formation of the concave portions 38 are performed in one step. Therefore, it is possible to simplify a process compared with the case in the above embodiment (FIGS. 2a and 2b, FIG. 3, and FIGS. 4a to 4d).

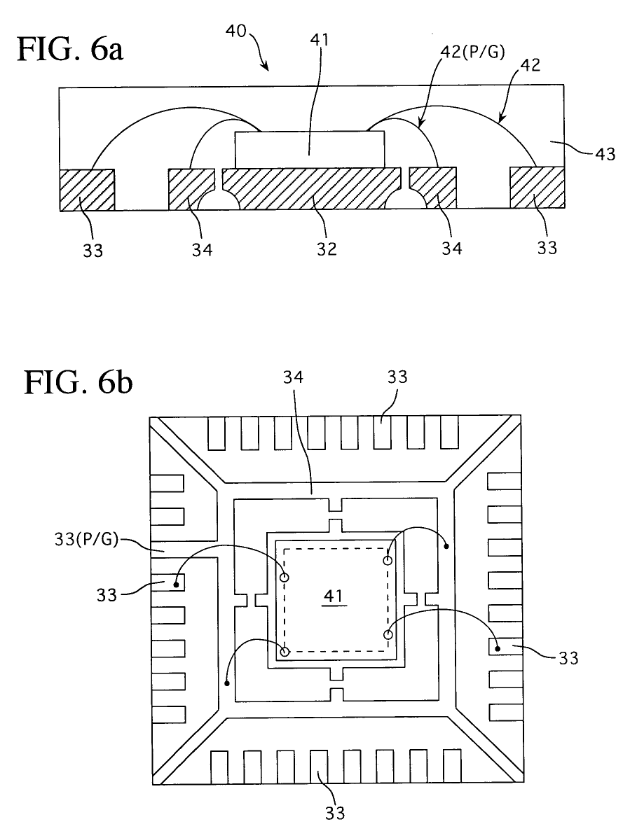

FIGS. 6a and 6b schematically show an example of a semiconductor device having the structure of a QFN package, which has been manufactured using the lead frame 30 of the above embodiment. FIG. 6a shows the cross-sectional constitution of the semiconductor device 40, and FIG. 6b shows the constitution seen from the top after wire bonding has been performed in a package assembly process.

In the semiconductor device 40 shown in FIGS. 6a and 6b, reference numeral 41 denotes a semiconductor element (chip) mounted on the die-pad 32, reference numerals 42 and 42(P/G) denote bonding wires each of which connects each electrode terminal (a signal terminal or a power/ground terminal) of the semiconductor element 41 to the corresponding lead 33 or the ring-shaped conductor portion 34, reference numeral 43 denotes sealing resin for protecting the semiconductor element 41, the bonding wires 42 and 42(P/G), and the like.

A method of manufacturing the semiconductor device 40 (QFN package) is the same as that of a prior art manufacturing process, and thus the detailed description thereof will be omitted. The method of manufacturing the semiconductor device 40 (QFN package) basically includes the step (die bonding) of mounting a semiconductor element 41 on each die-pad 32 of the lead frame 30; the step (wire bonding) of electrically connecting each electrode terminal of the semiconductor element 41 to the corresponding lead 33 or the ring-shaped conductor portion 34 with the bonding wire 42 or 42(P/G); the step (mass molding or individual molding) of sealing each semiconductor element 41, the bonding wires 42 and 42(P/G), and the like with the sealing resin; and the step (dicing) of dividing the lead frame (base frame 31) for each package using a dicer or the like after peeling off the adhesive tape 37.

As described above, according to the constitution of the lead frame 30 (FIGS. 2a and 2b) according to the first embodiment, the conductor portion 34 for power/ground terminal is formed in the shape of a ring around the die-pad 32, and the conductor portion 34 is connected to one lead 33(P/G) among the 32 leads 33, which is assigned exclusively for power/ground terminal. Accordingly, where a semiconductor element 41 (FIGS. 6a and 6b) provided with a plurality of power/ground terminals is mounted on the lead frame, each power/ground terminal of the semiconductor element 41 can be connected to the common lead 33(P/G) exclusively for power/ground terminal by connecting each power/ground terminal to the ring-shaped conductor portion 34, not by connecting each power/ground terminal to the corresponding lead in a one-to-one relationship as in the prior art.

In other words, the number of leads connected to the power/ground terminals of the semiconductor element 41 to be mounted thereon can be reduced to a minimum of one (lead 33(P/G)). This eliminates the need for a considerable number of leads exclusively for power/ground terminals, which have been heretofore required. Thus, the size of a package (semiconductor device 40) can be reduced by the amount corresponding to the no longer required leads.

Moreover, the conductor portion 34 is formed in the shape of a ring around the die-pad 32 (i.e., over a relatively wide area). Accordingly, when wire bonding is performed in a package (semiconductor device 40) assembly process, a sufficient space is ensured for wire bonding positions on the conductor portion 34, thereby making it possible to improve the degree of freedom of a wire bonding position.

Furthermore, operating current can be made uniform because the conductor portion 34 for power/ground terminal is formed in the shape of a ring around the die-pad 32.

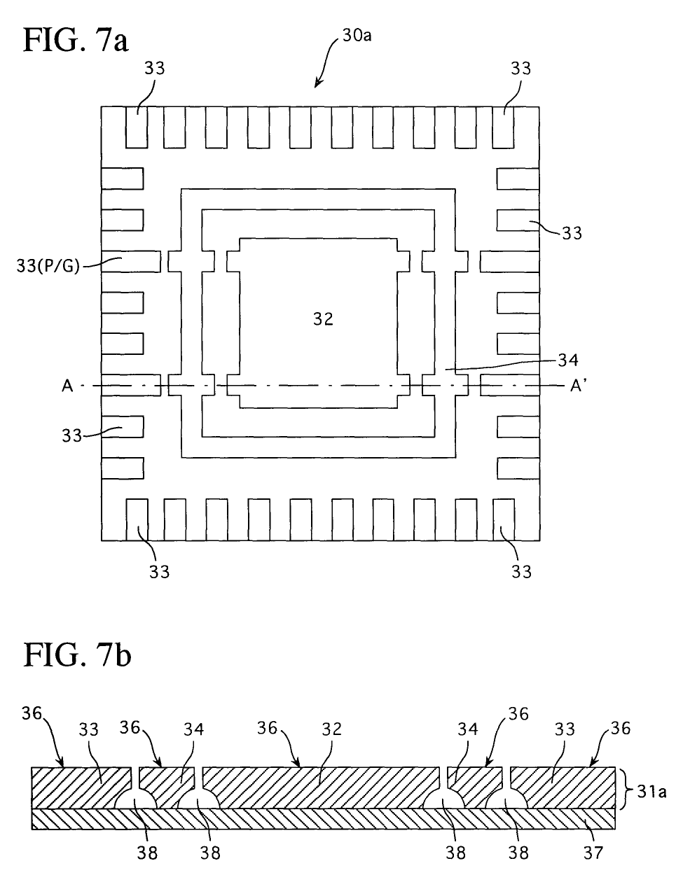

FIGS. 7a and 7b schematically show the constitution of a lead frame for use in a leadless package, such as a QFN package, according to a second embodiment of the present invention. FIG. 7a shows, in plan view, the constitution of part (a portion corresponding to an area to be ultimately separated as an individual semiconductor device) of the lead frame, and FIG. 7b shows the cross-sectional structure of the lead frame seen along the line A-A′ in FIG. 7a.

The lead frame 30a according to the present embodiment is basically different from the lead frame 30 according to the first embodiment (FIGS. 2a to 2b) in that four support bars 35 for supporting a ring-shaped conductor portion 34 are not provided and that the conductor portion 34 is not linked (connected) to a lead 33(P/G) for power/ground terminal. The other components are the same as those of the first embodiment, and thus the explanation thereof will be omitted.

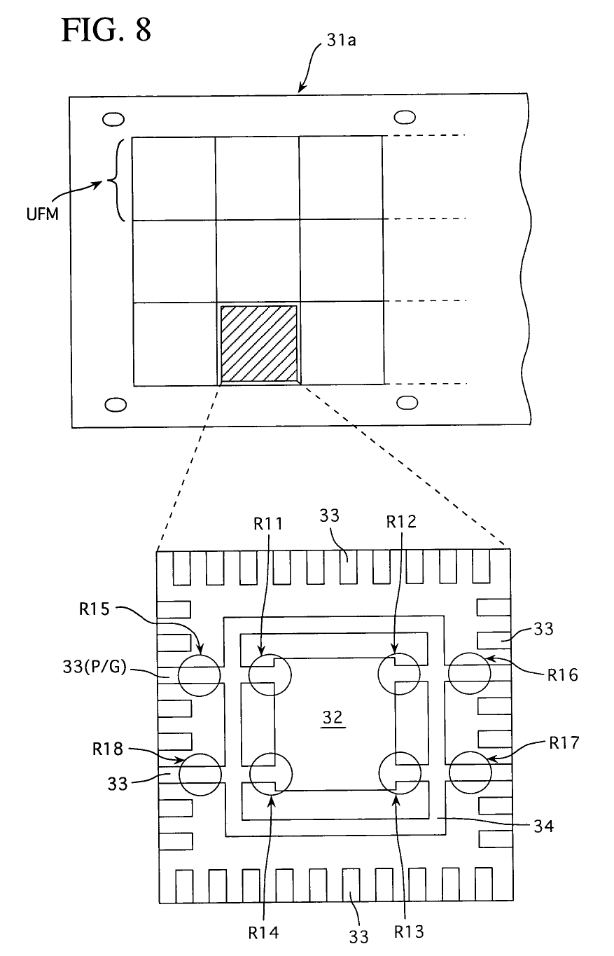

Similarly, a method of manufacturing the lead frame 30a is basically the same as the manufacturing process shown in FIG. 3 and FIGS. 4a to 4d or the process shown in FIGS. 5a to 5c, and thus the detailed explanation thereof will be omitted. Note, in the case of the second embodiment, as shown in FIG. 8, the pattern shape of a base frame 31a is different due to the above difference in constitution. Specifically, in each unit base frame UFM of the base frame 31a, the conductor portion 34 is formed in the shape of a ring around a die-pad 32 in the area between the die-pad 32 and leads 33. The conductor portion 34 is connected to the die-pad 32 at four positions (portions surrounded by circles denoted by R11 to R14 in this drawing) and connected to four leads 33 (among these, one lead is the lead 33(P/G) for power/ground terminal) at four positions (portions surrounded by circles denoted by R15 to R18 in this drawing). Moreover, concave portions 38 are formed at these eight portions R11 to R18 (FIG. 8), and these portions are ultimately cut off.

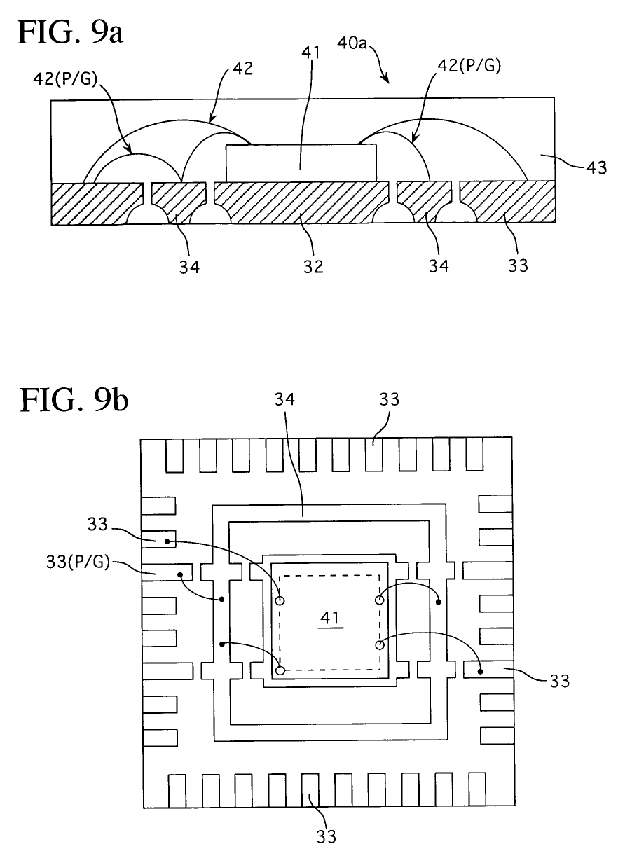

FIGS. 9a and 9b schematically show an example of a semiconductor device having the structure of a QFN package, which has been manufactured using the lead frame 30a of the second embodiment. FIG. 9a shows the cross-sectional constitution of the semiconductor device 40a, and FIG. 9b shows the constitution seen from the top after wire bonding has been performed in a package assembly process. In these drawings, reference numeral 41 denotes a semiconductor element (chip), reference numerals 42 and 42(P/G) denote bonding wires, and reference numeral 43 denotes sealing resin. As shown in these drawings, the conductor portion 34 is electrically connected to the lead 33(P/G) for power/ground terminal through the bonding wire 42(P/G).

According to the constitution of the lead frame 30a (FIGS. 7a and 7b) of the second embodiment, there is obtained an advantage in that a plurality of leads 33 (four leads in the example shown in FIGS. 7a and 7b) can be additionally provided in the space produced by not providing four support bars 35, in addition to the effect obtained in the above first embodiment. This contributes to increasing the number of pins.

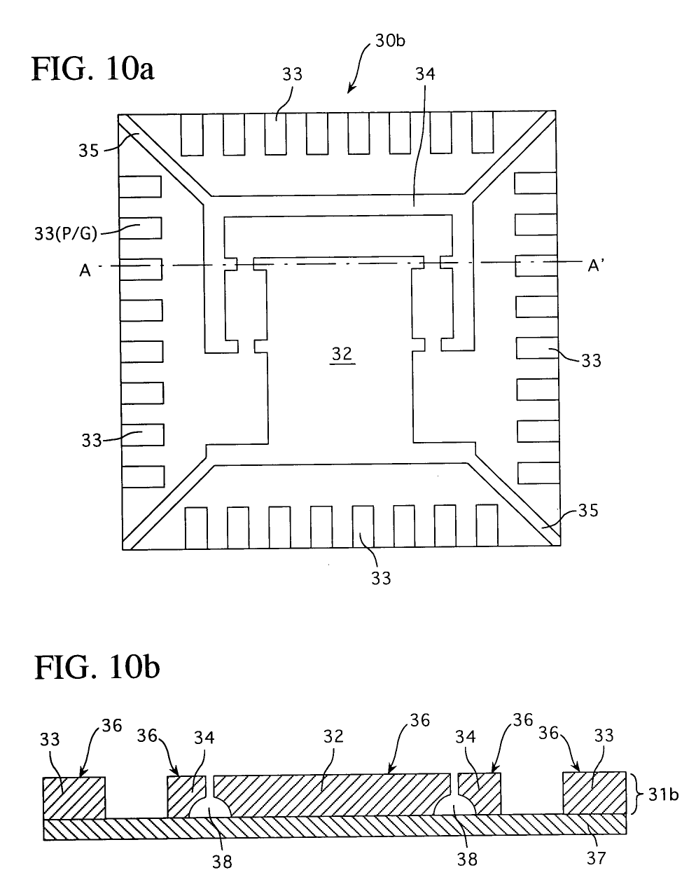

Although, in the above-described first and second embodiments, the explanation has been made taking the case as an example where the conductor portion 34 for power/ground terminal is formed in the shape of a ring around the die-pad 32, it is of course that the shape of the conductor portion 34 is not limited to the shape of a ring. In short, it is sufficient that the conductor portion 34 is formed to at least partially surround the die-pad 32 in the area between the die-pad 32 and the leads 33. An example thereof is shown in FIGS. 10a and 10b.

FIGS. 10a and 10b schematically show the constitution of a lead frame for use in a leadless package, such as a QFN package, according to a third embodiment of the present invention. FIG. 10a shows the structure of part (a portion corresponding to an area to be ultimately separated as an individual semiconductor device) of the lead frame, and FIG. 10b shows the cross-sectional structure of the lead frame seen along the line A-A′ in FIG. 10a.

The lead frame 30b according to the present embodiment is basically different from the lead frame 30 according to the first embodiment (FIGS. 2a to 2b) in that the conductor portion 34 is formed to partially surround a die-pad 32 and that the conductor portion 34 is not linked (connected) to a lead 33(P/G) for power/ground terminal. The other components are the same as those of the first embodiment, and thus the explanation thereof will be omitted.

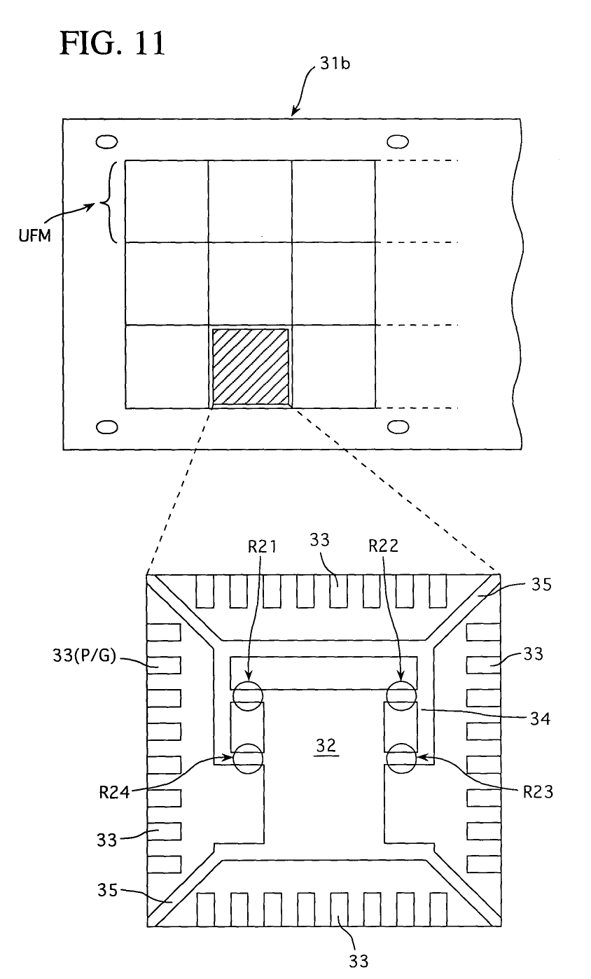

Similarly, a method of manufacturing the lead frame 30b is basically the same as the manufacturing process shown in FIG. 3 and FIGS. 4a to 4d or the process shown in FIGS. 5a to 5c, and thus the detailed explanation thereof will be omitted. Note, in the case of the third embodiment, as shown in FIG. 11, the pattern shape of a base frame 31b is different due to the above difference in constitution. Specifically, in each unit base frame UFM of the base frame 31b, the conductor portion 34 is formed to partially surround the die-pad 32 in the area between the die-pad 32 and the leads 33. The conductor portion 34 is connected to the die-pad 32 at four positions (portions surrounded by circles denoted by R21 to R24 in this drawing). Moreover, concave portions 38 are formed at these four portions R21 to R24 (FIG. 11), and these portions are ultimately cut off.

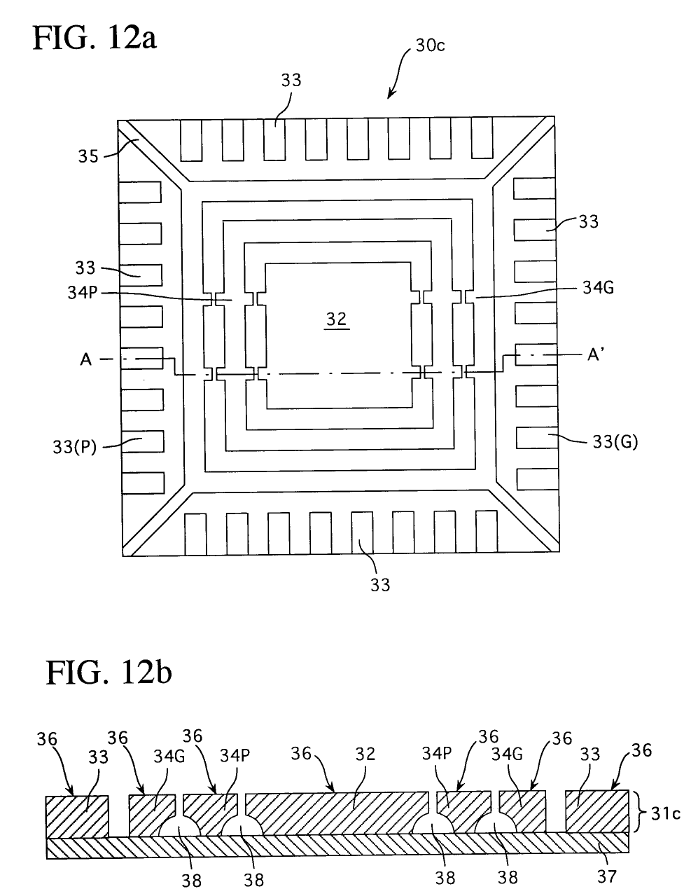

Although, in the above first and second embodiments, a description has been made taking the case as an example where the conductor portion 34 for power/ground terminal is formed in the form of a single ring around the die-pad 32, a conductor portion exclusively for power terminal and a conductor portion exclusively for ground terminal may be separately formed (in the form of double rings). An example thereof is shown in FIGS. 12a and 12b.

FIGS. 12a and 12b schematically show the constitution of a lead frame for use in a leadless package, such as a QFN package, according to a fourth embodiment of the present invention. FIG. 12a shows the constitution seen from the top of part (a portion corresponding to an area to be ultimately separated as an individual semiconductor device) of the lead frame, and FIG. 12b shows the cross-sectional structure of the lead frame seen along the line A-A′ in FIG. 12a.

The lead frame 30c according to the present embodiment is basically different from the lead frame 30 according to the first embodiment (FIGS. 2a to 2b) in that a ring-shaped conductor portion 34P (for power terminal) is further formed inside a ring-shaped conductor portion 34G (for ground terminal) supported by four support bars 35 and that none of the conductor portions 34P and 34G is linked (connected) to any of a lead 33(P) for power terminal and a lead 33(G) for ground terminal. The other components are the same as those of the first embodiment, and thus the explanation thereof will be omitted.

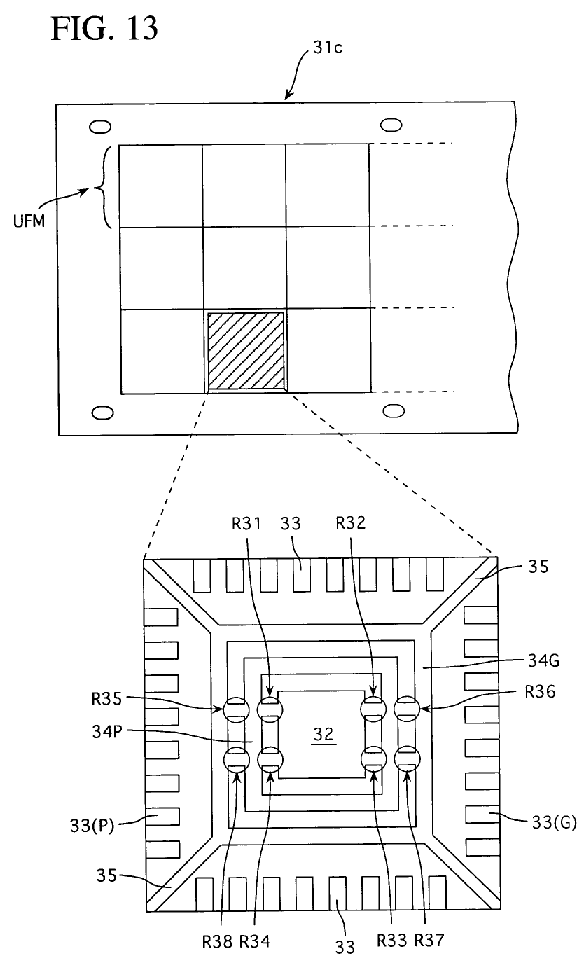

Similarly, a method of manufacturing the lead frame 30c is basically the same as the manufacturing process shown in FIG. 3 and FIGS. 4a to 4d or the process shown in FIGS. 5a to 5c, and thus the detailed explanation thereof will be omitted. Note, in the case of the fourth embodiment, as shown in FIG. 13, the pattern shape of a base frame 31c is different due to the above difference in constitution. Specifically, in each unit base frame UFM of the base frame 31c, the conductor portions 34P and 34G are formed in the form of double rings around a die-pad 32 in the area between the die-pad 32 and leads 33. The conductor portion 34P for power terminal is connected to the die-pad 32 at four positions (portions surrounded by circles denoted by R31 to R34 in this drawing), and the conductor portion 34G for ground terminal is connected to the conductor portion 34P for power terminals at four positions (portions surrounded by circles denoted by R35 to R38 in this drawing). Moreover, concave portions 38 are formed at these eight portions R31 to R38 (FIG. 13), and these portions are ultimately cut off.

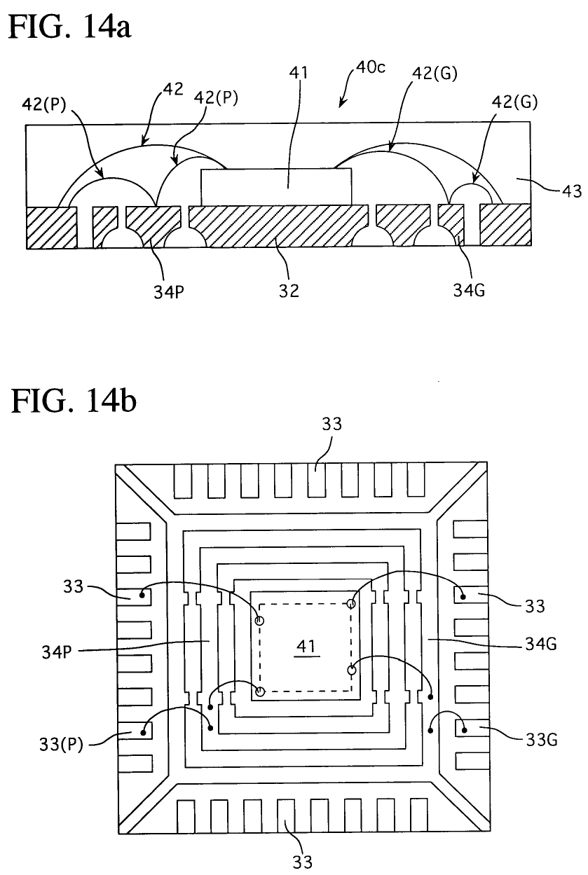

FIGS. 14a and 14b schematically show an example of a semiconductor device having the structure of a QFN package, which has been manufactured using the lead frame 30c of the fourth embodiment. FIG. 14a shows the cross-sectional constitution of the semiconductor device 40c, and FIG. 14b shows the constitution seen from the top after wire bonding has been performed in a package assembly process. In these drawings, reference numeral 41 denotes a semiconductor element (chip), reference numerals 42, 42(P), and 42(G) denote bonding wires, reference numeral 43 denotes sealing resin. As shown in these drawings, the conductor portion 34P is electrically connected to the lead 33(P) for power terminal using the bonding wire 42(P), and the conductor portion 34G is electrically connected to the lead 33(G) for ground terminal using the bonding wire 42(G).

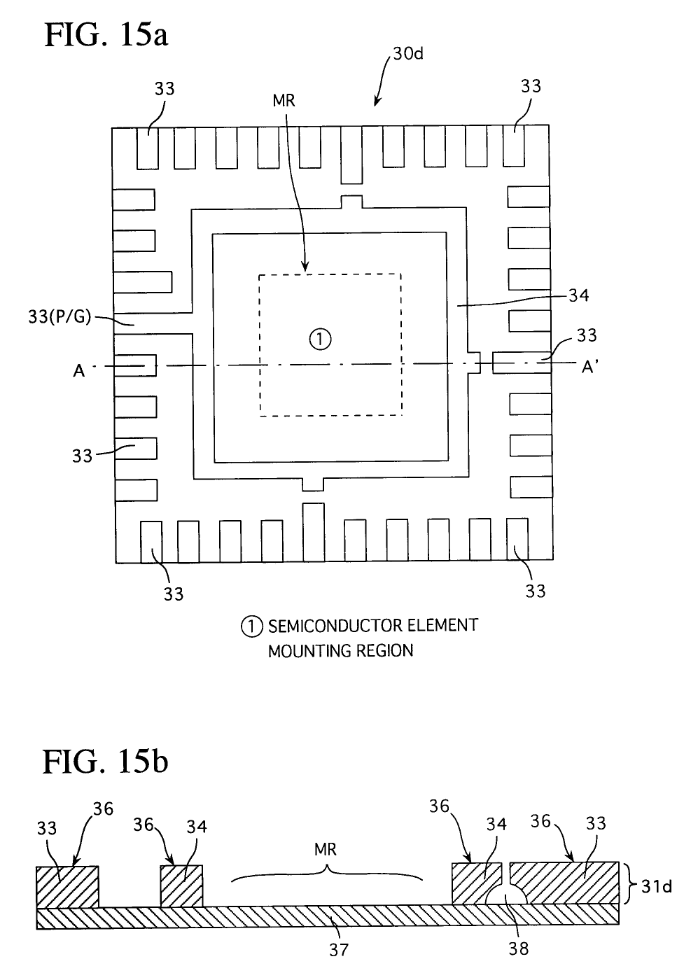

In the above first to fourth embodiments, the explanation has been made taking the case as an example where the die-pad 32 for mounting a semiconductor element is delimited on a lead frame. However, among lead frames, there are ones having forms where such die-pads are not delimited. An example thereof is shown in FIGS. 15a and 15b.

FIGS. 15a and 15b schematically show the constitution of a lead frame for use in a leadless package, such as a QFN package, according to a fifth embodiment of the present invention. FIG. 15a shows the constitution seen from the top of part (a portion corresponding to an area to be ultimately separated as an individual semiconductor device) of the lead frame, and FIG. 15b shows the cross-sectional structure of the lead frame seen along the line A-A′ in FIG. 15a.

The lead frame 30d according to the present embodiment is basically different from the lead frame 30 according to the first embodiment (FIGS. 2a to 2b) in that a semiconductor element mounting region MR is delimited instead of the die-pad 32 and that four support bars 35 supporting a ring-shaped conductor portion 34 are not provided. The other components are the same as those of the first embodiment, and thus the explanation thereof will be omitted.

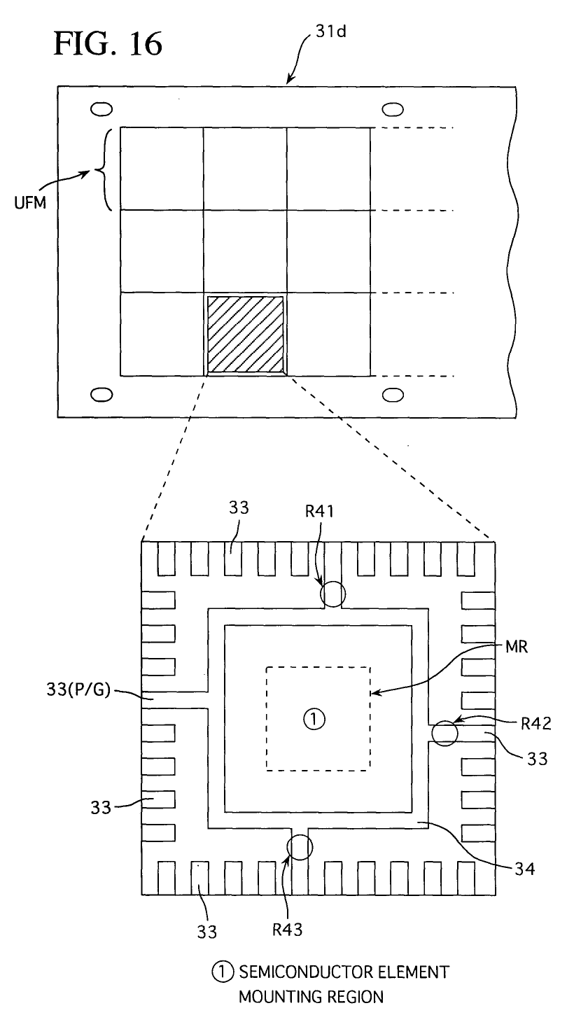

Similarly, a method of manufacturing the lead frame 30d is basically the same as the manufacturing process shown in FIG. 3 and FIGS. 4a to 4d or that shown in FIGS. 5a to 5c, and thus the detailed explanation thereof will be omitted. Note, in the case of the fifth embodiment, as shown in FIG. 16, the pattern shape of a base frame 31d is different due to the above difference in constitution. Specifically, in each unit base frame UFM of the base frame 31d, the conductor portion 34 is formed in the shape of a ring around a semiconductor element mounting region MR in the area between the semiconductor element mounting region MR and leads 33. The conductor portion 34 is connected to leads 33 at four portions. Moreover, concave portions 38 are formed at three portions (portions surrounded by circles denoted by R41 to R43 in this drawing) among these four portions (FIG. 16), and these three portions are ultimately cut off.

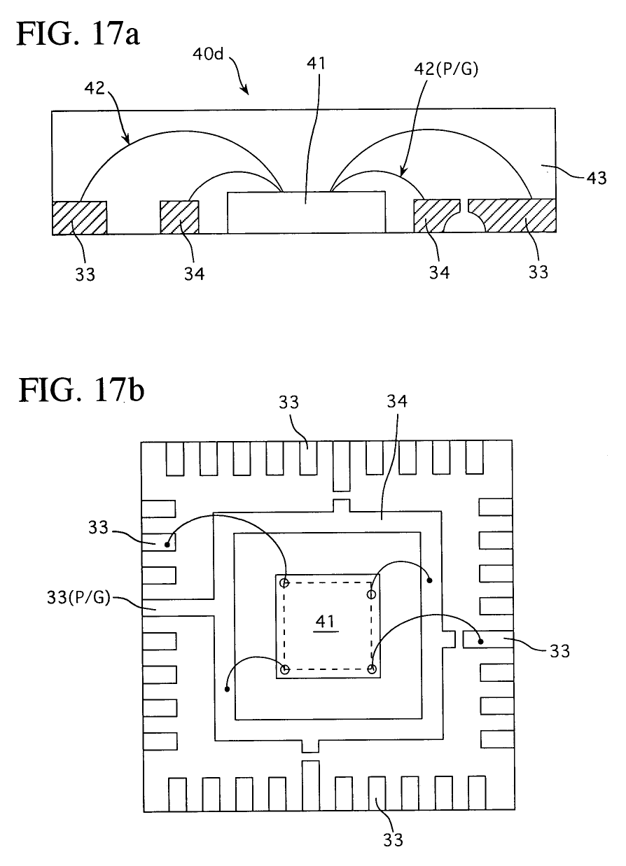

FIGS. 17a and 17b schematically show an example of a semiconductor device having the structure of a QFN package, which has been manufactured using the lead frame 30d of the fifth embodiment. FIG. 17a shows the cross-sectional constitution of the semiconductor device 40d, and FIG. 17b shows the constitution seen from the top after wire bonding has been performed in a package assembly process. In these drawings, reference numeral 41 denotes a semiconductor element (chip), reference numerals 42 and 42(P/G) denote bonding wires, and reference numeral 43 denotes sealing resin.

According to the constitution of the lead frame 30d (FIGS. 15a and 15b) of the fifth embodiment, the same effect as that obtained in the second embodiment (FIGS. 7a and 7b) can be obtained. In other words, there is obtained an advantage in that leads 33 can be additionally provided in the space produced by not providing support bars 35, in addition to the effect obtained in the first embodiment.

Although the first to fifth embodiments have been individually explained, it will be apparent to those skilled in the art that each embodiment can be appropriately modified or combined with other embodiments.

What is claimed is:

1. A lead frame comprising:
a die-pad delimited for a semiconductor element to be mounted thereon;
a plurality of leads arranged along a periphery of an area which is to be ultimately separated as a semiconductor device for the die-pad;
a conductor portion for power/ground terminal formed to at least partially surround the die-pad in an area between the die-pad and the plurality of leads corresponding to the die-pad,
wherein the die-pad, the plurality of leads, and the conductor portion for power/ground terminal are supported by an adhesive tape.

2. The lead frame according to claim 1, further comprising a plurality of support bars linked to the conductor portion for power/ground terminal, wherein the plurality of support bars are supported by the adhesive tape and extend to the periphery of the area which is to be ultimately separated as a semiconductor device.

3. The lead frame according to claim 2, wherein a plurality of leads are additionally provided instead of the plurality of support bars, in a space which the support bars have occupied.

4. The lead frame according to claim 1, wherein the conductor portion for power/ground terminal is formed in the shape of a ring around the corresponding die-pad.

5. The lead frame according to claim 1, wherein the conductor portion for power/ground terminal is doubly formed in the form of a ring around the corresponding die-pad.

6. The lead frame according to claim 1, wherein the conductor portion for power/ground terminal is formed to partially surround the corresponding die-pad.

7. The lead frame according to claim 1, wherein the conductor portion for power/ground terminal is connected to at least one lead among the plurality of leads.

8. A lead frame comprising:
a plurality of leads arranged along a periphery of an area which is to be ultimately separated as a semiconductor device for a semiconductor element mounting region; and
a conductor portion for power/ground terminal formed to at least partially surround a periphery of the semiconductor element mounting region in an area between the semiconductor element mounting region and the plurality of leads corresponding to the semiconductor element mounting region,
wherein the plurality of leads and the conductor portion for power/ground terminal are supported by an adhesive tape.

9. The lead frame according to claim 8, further comprising a plurality of support bars linked to the conductor portion for power/ground terminal, wherein the plurality of support bars are supported by the adhesive tape and extend to the periphery of the area which is to be ultimately separated as a semiconductor device.

10. The lead frame according to claim 9, wherein a plurality of leads are additionally provided instead of the plurality of support bars, in a space which the support bars have occupied.

11. The lead frame according to claim 8, wherein the conductor portion for power/ground terminal is formed in the shape of a ring around the corresponding semiconductor element mounting region.

12. The lead frame according to claim 8, wherein the conductor portion for power/ground terminal is doubly formed in the form of a ring around the corresponding semiconductor element mounting region.

13. The lead frame according to claim 8, wherein the conductor portion for power/ground terminal is formed to partially surround the corresponding semiconductor element mounting region.

14. The lead frame according to claim 8, wherein the conductor portion for power/ground terminal is connected to at least one lead among the plurality of leads.

15. A method of manufacturing a lead frame, comprising the steps of:
forming a base frame by etching or stamping a metal plate, in which a plurality of unit base frames are linked to one another, and have a die-pad, a plurality of leads corresponding to the die-pad, and a conductor portion for power/ground terminal arranged for a semiconductor element to be mounted on the die-pad, the conductor portion at least partially surrounding the die-pad in an area between the die-pad and the plurality of leads, and being linked to the die-pad;
forming a concave portion in a portion linking the conductor portion and the die-pad on one surface of the base frame;
attaching an adhesive tape on the surface of the base frame where the concave portion is formed; and
cutting off a portion of the base frame where the concave portion is formed.

16. The method according to claim 15, further comprising a step of forming a metal film on an entire surface of the base frame, between the step of forming a concave portion and the step of attaching an adhesive tape.

17. A method of manufacturing a lead frame, comprising the steps of:
forming a base frame by simultaneously etching a metal plate on both surfaces thereof using resist patterned in a predetermined shape for each surface of the metal plate, in which a plurality of unit base frames are linked to one another, and have a die-pad, a plurality of leads corresponding to the die-pad, and a conductor portion for power/ground terminal arranged for a semiconductor element to be mounted on the die-pad, the conductor portion at least partially surrounding the die-pad in an area between the die-pad and the plurality of leads, and being linked to the die-pad, and simultaneously forming a concave portion in a portion linking the conductor portion and the die-pad on one surface of the base frame;
attaching an adhesive tape on the surface of the base frame where the concave portion is formed; and
cutting off a portion of the base frame where the concave portion is formed.

18. The method according to claim 17, further comprising a step of forming a metal film on an entire surface of the base frame, between the step of forming a concave portion and the step of attaching an adhesive tape.

19. A method of manufacturing a lead frame, comprising the steps of:
forming a base frame by etching or stamping a metal plate, in which a plurality of unit base frames are linked to one another, and have a semiconductor element mounting region, a plurality of leads corresponding to the semiconductor element mounting region, and a conductor portion for power/ground terminal arranged for a semiconductor element to be mounted on the semiconductor element mounting region, the conductor portion at least partially surrounding the semiconductor element mounting region in an area between the semiconductor element mounting region and the plurality of leads, and being linked to at least one lead among the plurality of leads;
forming a concave portion in a portion linking the conductor portion and the at least one lead on one surface of the base frame;
attaching an adhesive tape on the surface of the base frame where the concave portion is formed; and
cutting off a portion of the base frame where the concave portion is formed.

20. The method according to claim 19, further comprising a step of forming a metal film on an entire surface of the base frame, between the step of forming a concave portion and the step of attaching an adhesive tape.

21. A method of manufacturing a lead frame, comprising the steps of:
forming a base frame by simultaneously etching a metal plate from both surfaces thereof using resist patterned in a predetermined shape for each surface of the metal plate, in which a plurality of unit base frames are linked to one another, and have a semiconductor element mounting region, a plurality of leads corresponding to the semiconductor element mounting region, and a conductor portion for power/ground terminal arranged for a semiconductor element to be mounted on the semiconductor element mounting region, the conductor portion at least partially surrounding the semiconductor element mounting region in an area between the semiconductor element mounting region and the plurality of leads, and being linked to at least one lead among the plurality of leads, and simultaneously forming a concave portion in a portion linking the conductor portion and the at least one lead on one surface of the base frame;
attaching an adhesive tape on the surface of the base frame where the concave portion is formed; and
cutting off a portion of the base frame where the concave portion is formed.

22. The method according to claim 21, further comprising a step of forming a metal film on an entire surface of the base frame, between the step of forming a concave portion and the step of attaching an adhesive tape.
